(19) United States
(12) Patent Application Publication
(10) Pub. No.: US 2013/0237063 A1
(43) Pub. Date: Sep. 12, 2013

(54) SPLIT PUMPING METHOD, APPARATUS, AND SYSTEM

(71) Applicants: SESHASAYEE VARADARAJAN, LAKE OSWEGO, OR (US); ANTONIO XAVIER, WEST LINN, OR (US); Ramesh CHANDRASEKHARAN, PORTLAND, OR (US); DIRK RUDOLPH, DUNDEE, OR (US)

(72) Inventors: SESHASAYEE VARADARAJAN, LAKE OSWEGO, OR (US); ANTONIO XAVIER, WEST LINN, OR (US); Ramesh CHANDRASEKHARAN, PORTLAND, OR (US); DIRK RUDOLPH, DUNDEE, OR (US)

(21) Appl. No.: 13/783,059

(22) Filed: Mar. 1, 2013

Related U.S. Application Data
(60) Provisional application No. 61/609,199, filed on Mar. 9, 2012.

(51) Int. Cl. H01L 21/67; H01L 21/02

(52) U.S. Cl. CPC H01L 21/67011; H01L 21/02263
USPC 438/758; 118/715; 118/696

(57) ABSTRACT

A split-pumping system and method for semiconductor fabrication process chambers is provided. The split pumping method may provide two separate exhaust paths, each configured to evacuate a different process gas. The exhaust paths may be configured to not evacuate process gases other than the process gas that the exhaust path is configured to evacuate.

### CROSS REFERENCE TO RELATED APPLICATION

This application claims benefit under 35 U.S.C. §119(e) to U.S. Provisional Application No. 61/609,199, filed Mar. 9, 2012, titled “SPLIT PUMPING METHOD, APPARATUS AND SYSTEM,” which is incorporated by reference herein in its entirety.

### BACKGROUND

In many semiconductor fabrication processes, a semiconductor wafer may be placed in a reaction chamber or reactor and exposed to one or more process chemicals. These chemicals may react with the semiconductor wafer and cause the semiconductor wafer to experience deposition, etch, cure, or other processes.

One type of semiconductor fabrication process that has recently entered widespread use in the industry is atomic layer deposition (ALD). In a typical ALD process, a wafer is exposed in a repeating, alternating fashion to two or more different process gases. The flows of the process gases across the wafer are typically separated in time to prevent mixing of the process gases in the wafer reaction area. The process gas flows may also be very short, e.g., on the order of 2-3 seconds or less. In ALD, each alternating gas flow cycle may result in the deposition of a highly conformal layer between approximately 0.1to 3 Å thick. Due to the low thickness of these layers, an ALD process may involve hundreds of alternating ALD cycles to achieve a desired thickness.

During a typical ALD process cycle, a first process gas may be flowed across a wafer and experience a self-limiting reaction with the surface of the wafer to form a conformal layer. Once the first process gas stops reacting with the wafer, further application of the first process gas will not, absent further intervention, result in further layer formation—this behavior results in layers of a very uniform thickness or high conformality. To allow an additional layer to be added (thus increasing the thickness of the deposited material further), a second process gas may then be applied to the wafer to “reset” the exposed surface of the layer after purging the volume around the wafer with a purge gas to allow a subsequent re-exposure of the wafer to the first process gas to result in the formation of an additional layer. Once the reset is complete and the second process gas is stopped, the first process gas may be restarted, after again purging the volume around the wafer with a purge gas, and another layer may be deposited. This process may be repeated until the desired deposition thickness is reached. If the first process gas and the second process gas are mixed, however, the ALD process may exhibit characteristics of a conventional chemical vapor deposition process (CVD), which is a process that is less time-intensive but that also provides deposition layers without the high conformality provided by ALD. Thus, to prevent the conversion of an ALD process into a de facto CVD process, the first process gas flows and the second process gas flows across the wafer are separated in time so that there is little to no mixing of the first process gas and the second process gas near the wafer.

In conventional ALD apparatuses, as well as apparatuses for other semiconductor processes where gas flows of different process gases across the wafer may be separated in time, the process gases used, including the first process gas, the second process gas, any carrier gases used, and any other gases involved in such processes, may be exhausted from the reaction chamber of the apparatus via a common exhaust line.

### SUMMARY

Details of one or more implementations of the subject matter described in this specification are set forth in the accompanying drawings and the description below. Other features, aspects, and advantages will become apparent from the description, the drawings, and the claims. Note that the relative dimensions of the following Figures may not be drawn to scale unless specifically indicated as being scaled drawings.

In some implementations, an apparatus for semiconductor processing operations may be provided. The apparatus may include a reaction chamber, a first foreline fluidly connected with the reaction chamber, and a second foreline fluidly connected with the reaction chamber. The first foreline may be configured to evacuate a first process gas from the reaction chamber and the second foreline may be configured to evacuate a second process gas from the chamber.

In some such implementations, the first foreline and the second foreline may both be fluidly connected with the reaction chamber downstream of any process gas inlet ports into the reaction chamber. In some implementations of the apparatus, the first foreline and the second foreline may be fluidly connected with the reaction chamber via separate ports.

In some implementations of the apparatus, the apparatus may also include a common foreline fluidly connecting the first foreline and the second foreline to the reaction chamber. In such implementations, the common foreline may be located upstream of the first foreline and the second foreline. In some such implementations, the apparatus may include a common valve configured to regulate fluid flow of the common foreline. The common valve may be located between the reaction chamber and the first foreline and between the reaction chamber and the second foreline. In some further such implementations of the apparatus, the common valve may include a throttling component and a shut-off component.

In some further implementations, the apparatus may include a first valve located on the first foreline and configured to regulate fluid flow through the first foreline, and a second valve located on the second foreline and configured to regulate fluid flow through the second foreline. In some such implementations, the first valve and the second valve may both be non-sealing, high-speed throttle valves. In some such implementations, the non-sealing, high-speed throttle valves may have actuation speeds of less than 1 second and leak rates of less than 1000 sccm from 1 atmosphere to vacuum. In some other implementations, the first valve and the second valve may both be mechanically-sealing, high-speed valves.

In some implementations, a first vacuum pump with a first suction inlet fluidly connected with the first foreline and a second vacuum pump with a second suction inlet fluidly connected with the second foreline may be provided. In some such implementations, the first vacuum pump and the second vacuum pump may have substantially similar performance characteristics and the first foreline and the second foreline may have substantially the same length and diameter.

In some implementations, the apparatus may also include a first exhaust line fluidly connected with a first exhaust outlet of the first vacuum pump and with an abatement system and a second exhaust line fluidly connected with a second exhaust outlet of the second vacuum pump and with the abatement system. In some such implementations, the apparatus may include the abatement system.

In some implementations, the apparatus may include a third foreline fluidly connected with the reaction chamber. The third foreline may be configured to evacuate a third process gas from the reaction chamber. The third process gas may be different from the first process gas and the second process gas. In some such implementations, the third foreline may be fluidly connected with the reaction chamber downstream of any process gas inlet ports in the reaction chamber

In some implementations, the apparatus may further include a controller including one or more processors and one or more memories. The one or more processors may be communicatively connected with the first valve and the second valve, and the one or more memories may store computer-executable instructions for controlling the one or more processors to: receive first data indicating that the first process gas is being flowed into the reaction chamber; responsive to receiving the first data, control the first valve to be in an open state and control the second valve to be in a substantially closed state; receive second data indicating that the second process gas is being flowed into the reaction chamber; and responsive to receiving the second data, control the second valve to be in an open state and control the first valve to be in a substantially closed state.

In some such implementations, the one or more memories may store further computer-executable instructions for further controlling the one or more processors to: receive third data indicating that purge gas is being flowed into the reaction chamber in association with purging the first process gas from the reaction chamber; responsive to receiving the third data, control the first valve to be in an open state and control the second valve to be in a substantially closed state; receive fourth data indicating that purge gas is being flowed into the reaction chamber in association with purging the second process gas from the reaction chamber; and responsive to receiving the fourth data, control the second valve to be in an open state and control the first valve to be in a substantially closed state.

In some implementations, a method of performing a semiconductor fabrication process may be provided, the method including a) supplying a first process gas to a wafer reaction area in a reaction chamber; b) purging the wafer reaction area of the first process gas by performing a first purge operation; c) drawing a vacuum on a first foreline fluidly connected with, and downstream of any process gas inlet ports in, the reaction chamber during (b); d) supplying a second process gas to the wafer reaction area; e) purging the wafer reaction area of the second process gas by performing a second purge operation; and f) drawing a vacuum on a second foreline fluidly connected with, and downstream of any process gas inlet ports in, the reaction chamber during (e), the second foreline separated from the first foreline such that gases in the first foreline do not mix with gases in the second foreline while the gases are in the first foreline and the second foreline. In some further implementations, the method may also include repeating (a) through (f) one or more times. In some further implementations, the method may also include g) drawing a vacuum on the first foreline during (a) and h) drawing a vacuum on the second foreline during (d). In some such implementations, the method may further include repeating (a) through (h) one or more times.

These aspects, and others, are described in more detail with reference to the drawings and the detailed description.

### BRIEF DESCRIPTION OF THE DRAWINGS

FIG. 1 depicts a schematic of one example of an implementation of a split-pumping exhaust system.

FIG. 2 depicts a process timeline showing various aspects of two cycles of a hypothetical deposition process.

FIG. 3 depicts the process of FIG. 2, but modified to include split-pumping activity.

FIG. 4 depicts a flow diagram of a split pumping technique.

FIG. 5 schematically shows a CFD process station 500 suitable for use with a split-pumping system.

FIG. 6 shows a schematic view of a multi-station processing tool.

### DETAILED DESCRIPTION

Provided herein are methods, apparatus and systems for pumping semiconductor processing reactants from a reaction chamber via separate exhaust lines. The concepts described herein are applicable in a variety of contexts but will be principally described in a semiconductor processing context.

The present inventors have realized that evacuation of certain reactants from a reaction chamber via a common exhaust line and pump system may result in deposition and/or other accumulation of non-volatile reaction products in the common exhaust line and/or pump system of the reaction chamber and may restrict or block flow through the common exhaust line or otherwise impede operation of the apparatus so that exhaust of reactants from the reaction chamber is no longer as efficient or effective. The present inventors have determined that such reaction products may be a more significant issue when two process gases have a non-zero reaction rate sufficient to create excess pressure, thus accelerating the generation of solid reaction products from the mixed gases. Such pressure rises may be even more problematic in portions of exhaust lines that are downstream of vacuum pumps in an exhaust system since such regions are already at higher pressure as compared with upstream portions of the exhaust system. The present inventors have also realized that some combinations of process gases (or byproducts caused by the reaction of such process gases) may experience very exothermic reactions when exposed to gases used during reaction chamber cleaning cycles, e.g., activated fluorine. These exothermic reactions can generate so much heat that exhaust lines from the pumps evacuating the reaction chamber can glow cherry red, causing a safety issue. The present inventors have realized methods, apparatuses, and systems that can be usefully applied to separately remove chemicals from a reaction chamber that could otherwise react to form a non-volatile reaction product in a common exhaust line from a reaction chamber.

In a variety of industrial processes, chemical reactants are provided to a reaction chamber where they react with each other or with objects in the reaction chamber, e.g., a substrate, to form a non-volatile reaction product, such as a deposition layer on a substrate. Unused reactants, for example gas phase reactants, may be removed from the chamber after a desired chemical reaction has occurred. As discussed above, the present inventors have realized that when reaction chamber effluent passes out of the reaction chamber via a single line, e.g., a single pump foreline (line preceding a pump), the mixed reactants may react to form non-volatile salts/solids within the foreline, pump, and exhaust line. These non-volatile solids may, for example, deposit or otherwise accumulate in the foreline or the pump, or may be trapped in the exhaust line between the pump and an abatement device. In accordance with the implementations discussed herein, separate forelines may be provided for exhausting different reactants from a common reaction chamber, thus substantially reducing or avoiding the generation of non-volatile reaction products in the exhaust system.

One technique for reducing such reaction by-product build up is to lengthen the purge operations performed between each first process gas/second process gas delivery phase. In many ALD processes, the wafer is contained within a “microvolume,” which is typically a subvolume of the reaction chamber within which the process gases are initially delivered and are typically concentrated. The use of microvolumes allows for smaller quantities of process gases to be used, resulting in less cost. Microvolumes also take less time to fill with gas, cutting down on process gas delivery time as well as purge cycle time. The purge cycle duration is typically long enough to purge the process gases within the microvolume, but not enough to purge the process gases outside of the microvolume but still within the reaction chamber or exhaust system. Thus, mixing of the process gases may typically occur in the portion of the reaction chamber outside of the microvolume and also within the exhaust system. By lengthening the purge duration, a process gas may be substantially evacuated from the reaction chamber and the exhaust system prior to introduction of a subsequent process gas, thus preventing or substantially mitigating the risk of process gas mixing. Given the volumes involved, however, such lengthened purge operations may substantially increase the amount of time required for each ALD cycle, thus rendering such lengthened purge operations economically infeasible in many ALD contexts.

Another technique for reducing such reaction by-product build-up is to incorporate a “cold trap” into the exhaust system. Cold traps are devices that provide a gas flow path across a cold, e.g., chilled or refrigerated, surface or surfaces. Condensable gases flowed through the cold trap may condense and freeze on the cold surface or surfaces, preventing gaseous mixing of the frozen condensate with other gases. Cold traps eventually fill up with frozen condensate and must be emptied periodically. In the context of semiconductor processes with long cycle times, e.g. furnace operation, such maintenance procedures may be carried out during portions of the cycle when the cold trap is not in use, e.g., during reaction chamber pump down, thus minimally impacting overall process cycle time. In the context of other processes with short process cycle times, such as, for example, ALD, there may not be any opportunity to perform such maintenance without significantly impacting overall process cycle time.

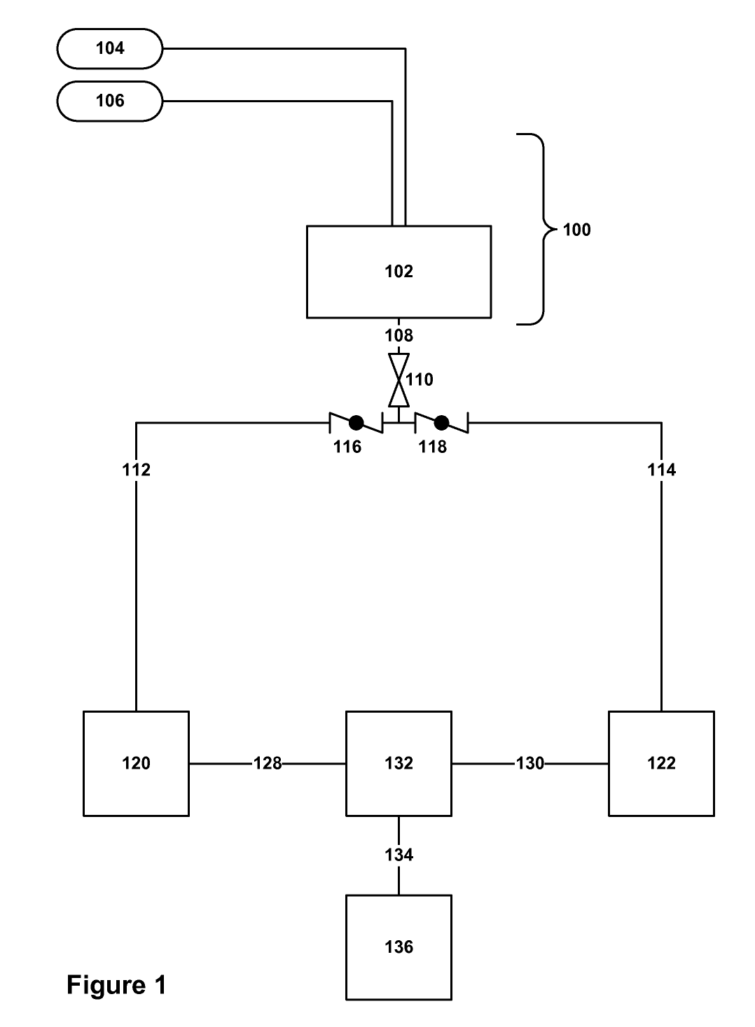

The present inventors provide the split-pumping apparatuses and techniques outlined herein as, among other things, an alternative to the extended purge and cold trap techniques discussed above. FIG. 1 depicts a schematic of one example of an implementation of a split-pumping system with a dual-foreline/pump exhaust system. A process module 100 may have a reaction chamber 102 that is connected with a first process gas supply 104 and a second process gas supply 106. Valves (not shown) may control the flow of the first process gas and the second process gas into the reaction chamber 102.

A common foreline 108 may exit the reaction chamber 102 and may include a common valve 110 configured to control fluid flow through the common foreline 108. The common valve 110 may be a gate valve with a throttling component, e.g., a pendulum valve, or may be provided using separate valves to provide both throttling and sealing functionality, e.g., a combination valve. The common valve 110 may have a throttling component, e.g., a throttle valve, that allows for pressure control upstream of the throttling component, i.e., of the reaction chamber 102. For example, a gate valve may be used in conjunction with a throttle valve to provide common valve 110.

The common foreline 108 may connect the reaction chamber 102 in the process module 100 to two separate forelines: a first foreline 112 and a second foreline 114. A first foreline valve 116 and a second foreline valve 118 may regulate fluid flow through the first foreline 112 and the second foreline 114, respectively. The first foreline valve 116 and the second foreline valve 118 may be located close to the points at which the first foreline 112 and the second foreline 114 are fluidly connected with the common foreline 108. A first pump 120 and a second pump 122 may be fluidly connected with ends of the first foreline 112 and the second foreline 114, respectively, opposite the ends of the first foreline 112 and the second foreline 114 where the first foreline valve 116 and the second foreline valve 116 are located. A first exhaust line 128 and a second exhaust line 130 may fluidly connect the first pump 120 and the second pump 122, respectively, with an abatement system 132. An exhaust duct 134 may be fluidly connected with the abatement system 132 and may be connected with an exhaust scrubber 136.

The system may be configured to operate, e.g., by opening and closing the first foreline valve 116 and the second foreline valve 118 in various sequences, such that substantially all of the first process gas is exhausted from the reaction chamber 102 via the first foreline 112, the first pump 120, and the first exhaust line 128 and substantially all of the second process gas is exhausted from the reaction chamber via the second foreline 114, the second pump 122, and the second exhaust line 130. In this manner, the first process gas and the second process gas may be prevented, or at least substantially prevented, from mixing within the first foreline 112, the second foreline 114, the first pump 120, the second pump 122, the first exhaust line 128, and the second exhaust line 130. This may substantially inhibit or prevent the accumulation of non-volatile reaction products within the first foreline 112, the second foreline 114, the first pump 120, the second pump 122, the first exhaust line 128, and the second exhaust line 130.

In some implementations, the common foreline 108 may not exist, and the first foreline 112 and the second foreline 114 may fluidly communicate with the reaction chamber 102 entirely separately. This, however, may require additional valve hardware and controllers since fine pressure control may be needed on both forelines, e.g., a throttle valve may be needed on each foreline for pressure-control purposes, rather than a single throttling component in the common valve 110. In the implementation shown, the valve 110 may provide reaction chamber pressure control regardless of whether the first foreline 112 or the second foreline 114 is active.

It is to be understood that while the system shown in FIG. 1 is designed to segregate exhaust flows of two process gases, similar techniques and equipment may be used to segregate exhaust flows of more than two process gases. For example, a separate foreline/pump/exhaust line may be provided for each process gas that needs to be isolated from the other process gases in order to prevent reaction products from being produced within the exhaust system. In determining the number of separate forelines/pumps/exhaust lines that may be required, the process gases in question may be grouped into non-reactive groups, and a separate foreline/pump/exhaust line may be provided for each group. For example, if process gases A, B, C, and D are used, A and B may be reactive with both C and D as well as with each other, but C and D may not be reactive with one another. In such a system, three separate forelines/pumps/exhaust lines may be used—one for exhausting only process gas A, one for exhausting only process gas B, and one for exhausting both process gas C and process gas D. In other implementations, each process gas used may have a dedicated and separate foreline/pump/exhaust line.

It is to be further understood that while the separate foreline/pump/exhaust lines shown in FIG. 1 are connected with a common abatement system 132, exhaust duct 134, and exhaust scrubber 136, other implementations may feature separate or partially separate abatement systems 132, exhaust ducts 134, and exhaust scrubbers 136. Since abatement systems typically render otherwise reactive chemicals inactive or less reactive, undesirable reactions between process gases within the abatement system may not be a concern and thus a common abatement system may often be used.

As discussed above, a number of semiconductor processing deposition techniques, including ALD, involve serially providing reactants to a reaction chamber for reaction to form a deposition layer on a substrate. ALD processes use surface-mediated deposition reactions to deposit films on a layer-by-layer basis. In one example ALD process, a substrate surface, including a population of surface active sites, is exposed to a gas phase distribution of a first film precursor (P1), or first process gas, within a reaction chamber. Some molecules of P1 may form a condensed phase atop the substrate surface, including chemisorbed species and physisorbed molecules of P1. The reaction chamber may then be evacuated to remove the gas phase and physisorbed P1 so that only chemisorbed species remain. A second film precursor (P2), or second process gas, may then be introduced to the reaction chamber so that some molecules of P2 adsorb to the substrate surface. The reaction chamber may then again be evacuated, this time to remove unbound P2. Subsequently, thermal energy may be provided to the substrate to activate surface reactions between adsorbed molecules of P1 and P2 and form a film layer. Finally, the reaction chamber may be evacuated to remove reaction by-products and possibly unreacted P1 and P2 and end the ALD cycle. Multiple successive ALD cycles may be performed to build film thickness. In other ALD processes, a plasma, or radicals from a plasma, may be used during some phases of the ALD cycle to assist in layer deposition.

A related technique, referred to as pulsed deposition layer (PDL) or rapid vapor deposition (RVD) processing, may be another semiconductor processing technique that may benefit from the split pumping exhaust systems discussed herein. PDL is similar to ALD in that reactant gases are introduced alternately over the substrate surface, but in PDL the film may grow more thickly. Thus, PDL methods allow for rapid film growth similar to using CVD methods but with the film conformality of ALD methods. Such a process is described in the paper by Hausmann et al. entitled Rapid Vapor Deposition of Highly Conformal Silica Nanolaminates (2002, Science, 298, pages 403-406) and U.S. Pat. No. 7,790,63, which are both hereby incorporated herein by reference in their entirety, in particular for their description of the PDL/RVD (rapid vapor deposition) technique, reaction chemistries, and apparatus for performing it.

Another technique for applying highly conformal films is plasma-activated conformal film deposition (CFD), as described further in copending U.S. patent application Ser. Nos. 13/084,305 and 13/084,399, both filed Apr. 11, 2011, which are incorporated herein by reference in their entirety, and in particular for their description of the CFD technique, reaction chemistries, and apparatus and systems for performing it. While some CFD techniques involve continuous flow of one of the reactants used, making it difficult to separately exhaust this reactant from other reactants used, other CFD techniques may involve sequential, alternating reactant flows similar to those used in ALD processes. Accordingly, some CFD apparatuses may also benefit from the split-pumping technologies outlined herein.

In some implementations, a split-pumping system may be used, for example, to support CFD processes for depositing a silicon nitride film by reaction of a silicon-containing reactant and one or more of a nitrogen-containing reactant and/or a nitrogen-containing reactant blend. Example silicon-containing reactants include, but are not limited to, bis(tertiarybutylamino)silane (SiH2(NHC(CH3)3)2 or BTBAS), dichlorosilane (SiH2Cl2), and chlorosilane (SiH3Cl). Example nitrogen-containing reactants include, but are not limited to, ammonia, nitrogen, and tert-butyl amine ((CH3)3CNH2 or t-butyl amine). An example nitrogen-containing reactant blend, includes, but is not limited to, a blend of nitrogen and hydrogen. Other reactants for CFD, as well as for other processes, such as those discussed above, may potentially be handled with a split-pumping system as well.

Implementations of the split-pumping apparatus/system described above may be used, for example, in conjunction with ALD, PDL, RVD, CFD, and similar processes. Since split-pumping systems as described herein are intended to prevent mixing of various process gases within the forelines, pumps, and exhaust lines associated with a reaction chamber, the foreline valves used may, in the ideal, be valves such as gate valves that are capable of mechanically sealing when closed. The mechanical seal may prevent process gas from leaking past the valve. The present inventors have realized, however, that in the context of processes having short-duration, high-frequency cycles, currently-available mechanical seal-type valves, such as gate valves, may result in unacceptable performance degradation. For example, in ALD processes, each process cycle may take on the order of a few seconds, and it is not uncommon for an ALD apparatus to perform hundreds of thousands of process cycles per month. Since the foreline valves would be opened and closed for each process cycle, the foreline valves could easily experience millions of operations per year, which would introduce considerable wear and tear on valves with mechanical seals. Such wear and tear could, in turn, lead to frequent, e.g., weekly, downtime so that the mechanical seals, e.g., elastomeric seals, may be replaced. Another performance issue with mechanical seal valves realized by the inventors is that mechanical seal valves commonly require several seconds to open or close. For example, if an example ALD cycle lasts 5 seconds and is implemented on an apparatus having a split-pumping system using mechanical seal valves having opening/closing times of 1 second in each direction this may add up to an additional 4 seconds to the overall ALD cycle time in some cases. This may have the effect of reducing the number of ALD cycles that may be performed in a given time window by ˜45%, resulting in a drastic decrease in throughput. It is to be understood that this example is hypothetical, and is intended only to illustrate certain potential issues that may be encountered using mechanically sealing valves—actual performance may be different depending on the equipment used, as well as the operating parameters adopted.

The present inventors have realized that, in some implementations, the foreline valves may be provided using high-speed, non-sealing throttle valves or other valves exhibiting similar non-sealing and response time characteristics. Non-sealing throttle valves are “non-contact” valves where the moving portion of the valve is not designed to contact the stationary part of the valve to form a seal when closed. Non-sealing throttle valves are not intended to mechanically seal and are instead chiefly intended to regulate pressure in non-zero gas flow situations. For example, a butterfly valve, which is a common type of throttle valve, may feature a cylindrical bore in the valve body and a rotatable “flapper.” The flapper may be a round disk having a slightly smaller outer diameter than the inner diameter of the cylindrical bore. A rotatable shaft may pass through the cylindrical bore along a diameter of the bore, and the flapper may be mounted on the shaft and be located in the center of the bore. When the shaft is rotated, the flapper may rotate within the bore. In the low-flow position, the flapper may be substantially perpendicular to the bore centerline. While the flapper may thus block most of the gas flow through the bore, the small gap between the outer edge of the flapper and the internal diameter of the bore may allow a small amount of gas leakage to occur. For example, some off-the-shelf non-sealing butterfly valves currently available exhibit leakage of less than 1000 sccm from atmospheric to vacuum, and less than 10 sccm from 10 Torr to vacuum, across the valve when the valve is closed. In the high-flow position, the flapper may be rotated approximately 90 degrees from the close position, leaving most of the cross-section of the bore at the flapper location unobstructed. This allows gas to flow relatively freely through the bore. In contrast to mechanically sealing valves, non-sealing throttle valves may provide for very fast actuation times, e.g., 0.2 seconds, which may, in the context of the 5-second ALD cycle example discussed above, result in at most 0.8 seconds being added to the overall ALD cycle time. In contrast to the ˜45% decrease in the number of ALD cycles that may be performed in a given window in the earlier example, the use of non-sealing throttle valves in place of mechanically sealing valves may result in only a ˜13% decrease in the number of ALD cycles that may be performed. It is to be understood that this example is hypothetical, and is intended only to illustrate certain potential issues that may be encountered using mechanically sealing valves—actual performance may be different depending on the equipment used, as well as the operating parameters adopted.

Non-sealing throttle valves are typically not used as mere shut-off valves since a) they are typically more expensive than mechanically sealing valves and b) they do not actually seal. Thus, the idea of using non-sealing throttle valves, or similar non-sealing valves effectively as shutoff valves for the first and second forelines in a split-pumping system runs contrary to commonly accepted practice. The use of non-sealing throttle valves as shut-off valves is still compatible with split-pumping systems since the limited leak rates of the valves may allow for only a very limited reaction between process gases within the forelines should any leakage of gases occur, causing minute, but typically acceptable, solids formation in the forelines.

The forelines, pumps, and exhaust lines used for each branch of a split-pumping system may be sized similarly to allow for similar pumping speeds to be used across each branch. In some implementations, however, each branch may have components sized independently of other components in other branches, e.g., some or all of the branches may have differently-sized components.

The equipment used for a split pumping system may be wholly or partially located in the subfloor of a semiconductor manufacturing facility (aside from, for example, the portions of the split pumping system that may connect with the reaction chamber or common foreline), or may be located above the floor.

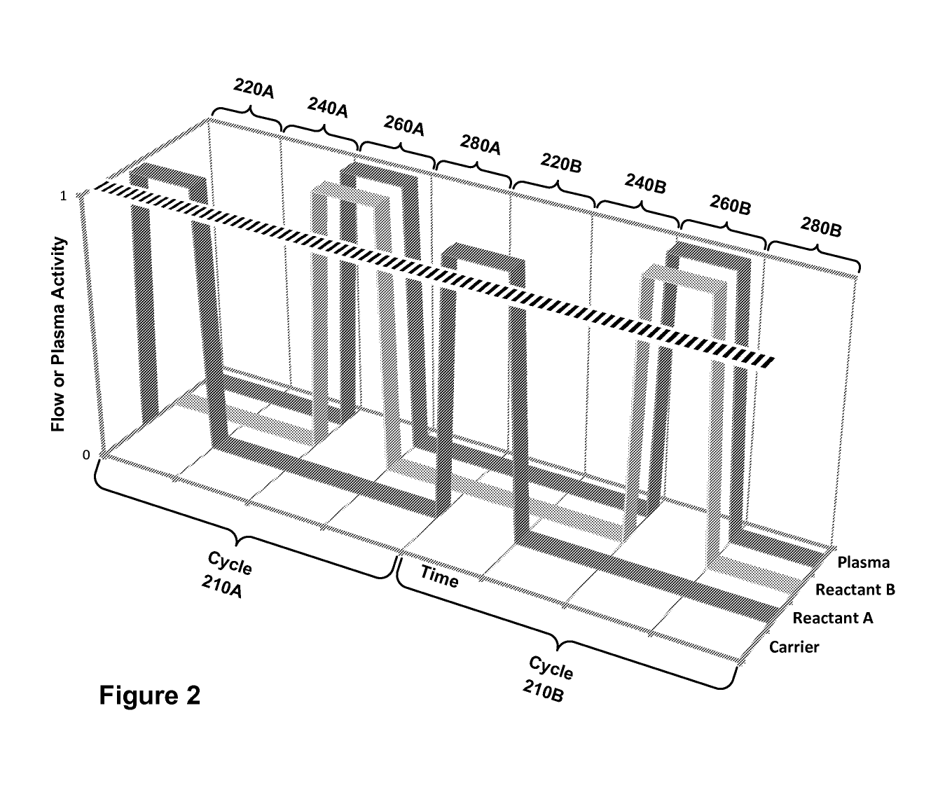

FIG. 2 depicts a process timeline showing various aspects of two cycles of a hypothetical deposition process. FIG. 2 may describe a variety of different time-separated dual-reactant processes such as ALD, PDL, and CFD from a general, high-level perspective. It is to be understood that the magnitudes and durations shown are not drawn to any particular scale, and that the magnitudes and durations associated with various operations may differ in actual practice despite being shown as substantially equal. For example, in some implementations, the carrier gas flow to the reaction chamber may be shut off or diverted during one or more of the process gas flows. In some implementations, the carrier gas flow may only be on during the purge flows.

Referring to FIG. 2, an inert carrier/purge gas is flowed during all phases of a process 200, including all of cycle 210A and cycle 210B. At reactant A exposure phase 220A, reactant A may be supplied at a controlled flow rate to a reaction chamber to saturate exposed surfaces of a substrate. Reactant A may be any suitable deposition reactant, for example, a nitrogen-containing reactant. While the implementation shown in FIG. 2 depicts reactant A exposure phase 220A as having a constant flow rate, it will be appreciated that any suitable flow of reactant A, including a variable flow, may be employed within the scope of the present disclosure. In some implementations, reactant A exposure phase 220A may have a duration that exceeds a substrate surface saturation time for reactant A. In the implementation shown, reactant A exposure phase 220A also includes the flow of the carrier gas, although in some implementations, the flow of the carrier gas may be varied or stopped during the reactant A exposure phase 220A. Example inert carrier gases include, but are not limited to, nitrogen, argon, and helium. The inert gas may be provided to assist with pressure and/or temperature control of the process station, evaporation of a liquid reactant, more rapid delivery of the reactant and/or as a sweep gas for removing process gases from the process station and/or process station plumbing.

In reactant A sweep operation 240A, the flow of reactant A may be stopped and the remaining reactant A in the wafer reaction area within the reaction chamber may be purged through the continued flow of the carrier gas. In implementations where the carrier gas is not flowed continuously, the carrier gas may be turned on to flow during the reactant A sweep operation 240A. At the end of the reactant A sweep operation 240A, the reaction area may be substantially free of unreacted reactant A.

Subsequent to the reactant A sweep operation 240A, a reactant B exposure phase 260A may occur. In the reactant B exposure phase 260A, the reactant B may be supplied at a controlled flow rate to the reaction chamber to saturate the exposed substrate surface. While the implementation of FIG. 2 depicts reactant B exposure phase 260A as having a constant flow rate, it will be appreciated that any suitable flow of reactant B, including a variable flow, may be employed within the scope of the present disclosure. Further, it will be appreciated that reactant B exposure phase 260A may have any suitable duration. In some implementations, reactant B exposure phase 260A may have a duration exceeding a substrate surface saturation time for reactant B. While the reactant B is flowing during the reactant B exposure phase 260A, a plasma may be activated using the reactant B to facilitate reaction of the reactant B with the wafer in the wafer reaction area. In some implementations, a plasma may not be needed or provided during the process operation.

In some implementations, the plasma ignited in the reactant B exposure phase 260A may be formed directly above the substrate surface. This may provide a greater plasma density and enhance a surface reaction rate between the reactant B and the wafer. For example, plasmas for CFD processes may be generated by applying a radio frequency (RF) field to a low-pressure volume of reactant B using two capacitively-coupled plates. Ionization of the reactant B between the plates by the RF field ignites the plasma, creating free electrons in the plasma discharge region. These electrons are accelerated by the RF field and may collide with gas phase reactant B molecules. Collision of these electrons with reactant B molecules may form radical species that participate in the deposition process. It will be appreciated that the RF field may be coupled via any suitable electrodes. Non-limiting examples of electrodes include process gas distribution showerheads and substrate support pedestals. It will be appreciated that plasmas for CFD processes may be formed by one or more suitable methods other than capacitive coupling of an RF field to a gas.

In some implementations, reactant B exposure phase 260A may have a duration that exceeds a time for plasma-activated radicals to interact with all exposed substrate surfaces and adsorbates, forming a continuous film atop the substrate surface.

In some implementations, a treatment other than a plasma treatment may be employed to modify the properties of the as-deposited film. Such treatments may include electromagnetic radiation treatments, thermal treatments (e.g., anneals or high temperature pulses), and the like. Any of these treatments may be performed alone or in combination with another treatment, including a plasma treatment. In some implementations, such an alternative treatment may be employed as a substitute for any of the above-described plasma treatments. In a specific implementation, the treatment may involve exposing the film to ultraviolet radiation.

Subsequent to the reactant B exposure phase 260A, a reactant B sweep operation 280A may occur. In reactant B sweep operation 280A, the flow of reactant B may be stopped and the remaining reactant B, as well as radicals produced by the reactant B plasma, may be purged from the wafer reaction area within the reaction chamber through the continued flow of the carrier gas. In implementations where the carrier gas is not flowed continuously, the carrier gas may be turned on to flow during the reactant B sweep operation 280A. At the end of the reactant B sweep operation 280A, the reaction area may be substantially free of unreacted reactant B.

After the reactant B sweep operation 280A has been completed, a second cycle 210B may be performed with similar or different parameters. The second cycle 210B may include a reactant A exposure phase 220A, a reactant A sweep operation 240A, a reactant B exposure phase 260A, and a reactant B sweep operation 280A. Multiple such cycles may be performed in successive fashion to build up a deposition layer of desired thickness.

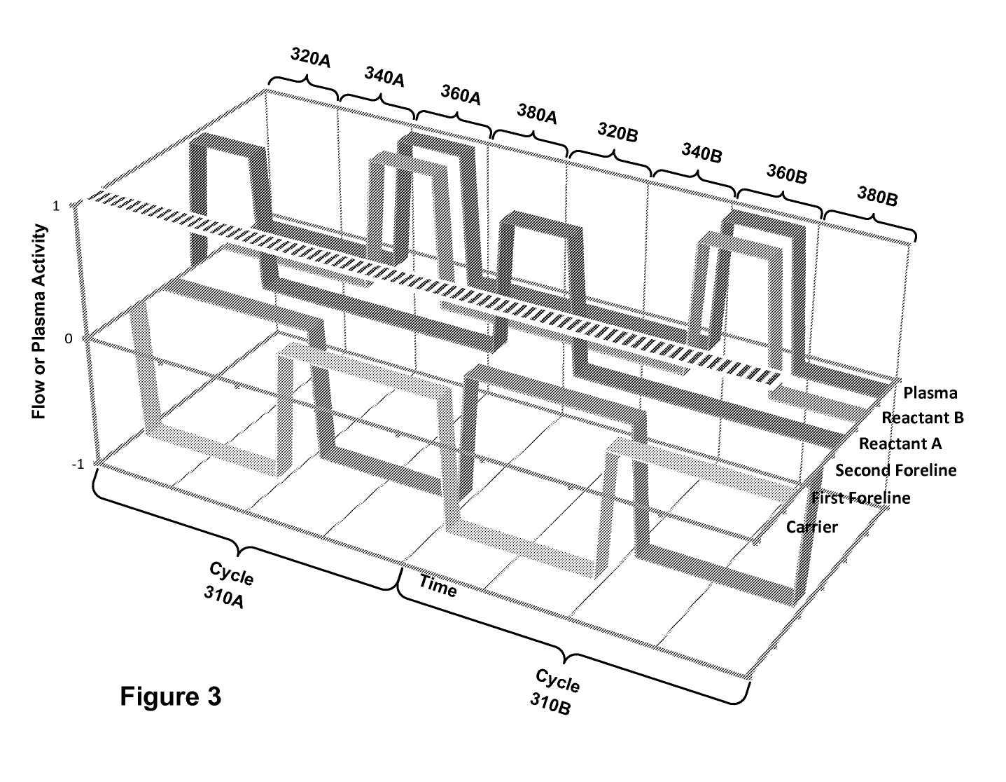

FIG. 3 depicts the process of FIG. 2, but modified to include split-pumping activity. As can be seen, two process cycles 310A and 310B are shown. Each process cycle 310A and 310B includes a reactant A exposure phase 320A/B, a reactant A sweep operation 340A/B, a reactant B exposure phase 360A/B, and a reactant B sweep operation 380A/B. Also visible in FIG. 3 are behavior plots for a first foreline and a second foreline. As can be seen, the first foreline may be active, e.g., drawing a vacuum, and the second foreline may be inactive, e.g., substantially not drawing a vacuum, during the reactant A exposure phases 320A/B and the reactant A sweep operations 340A/B. Thus, reactant A may be exhausted from the reaction chamber via the first foreline during the reactant A exposure phases 320A/B and the reactant A sweep operations 340A/B.

By contrast, the second foreline may be active, e.g., drawing a vacuum, and the first foreline may be inactive, e.g., substantially not drawing a vacuum, during the reactant B exposure phases 360A/B and the reactant B sweep operations 380A/B. Thus, reactant B may be exhausted from the reaction chamber via the first foreline during the reactant B exposure phases 360A/B and the reactant B sweep operations 380A/B. The exact timing of activation of each foreline may differ from that shown—for example, the foreline gas flows may not be started concurrently with the flows of the A and B reactants, but may be somewhat staggered in time to allow the time lag between when a gas flow is introduced to the wafer reaction area and when that gas reaches the reaction chamber exit to be accounted for. Similar timing adjustments may be made in determining when the foreline gas flows may be stopped.

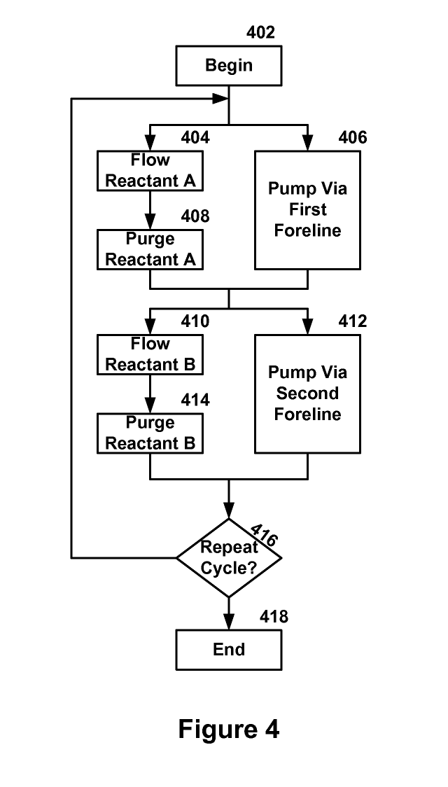

FIG. 4 depicts a flow diagram of a split pumping technique. The technique begins in block 402. In block 404, reactant A may be flowed into the reaction chamber and across a wafer. After the wafer exposure to reactant A has reached saturation levels, the reactant A may be purged from the reaction chamber in block 408. During one or both of block 404 and 408, the reactant A may be evacuated from the reaction chamber during block 406 by being pumped out via a first foreline.

Subsequently, in block 410, reactant B may be flowed into the reaction chamber and across a wafer. After the wafer exposure to reactant B has reached saturation levels, the reactant B may be purged from the reaction chamber in block 414. During one or both of block 410 and 414, the reactant B may be evacuated from the reaction chamber during block 412 by being pumped out via a second foreline. In block 416, a decision may be made as to whether or not further process cycles are needed. If so, the technique may return to blocks 404 and 406. If not, the technique may end in block 418.

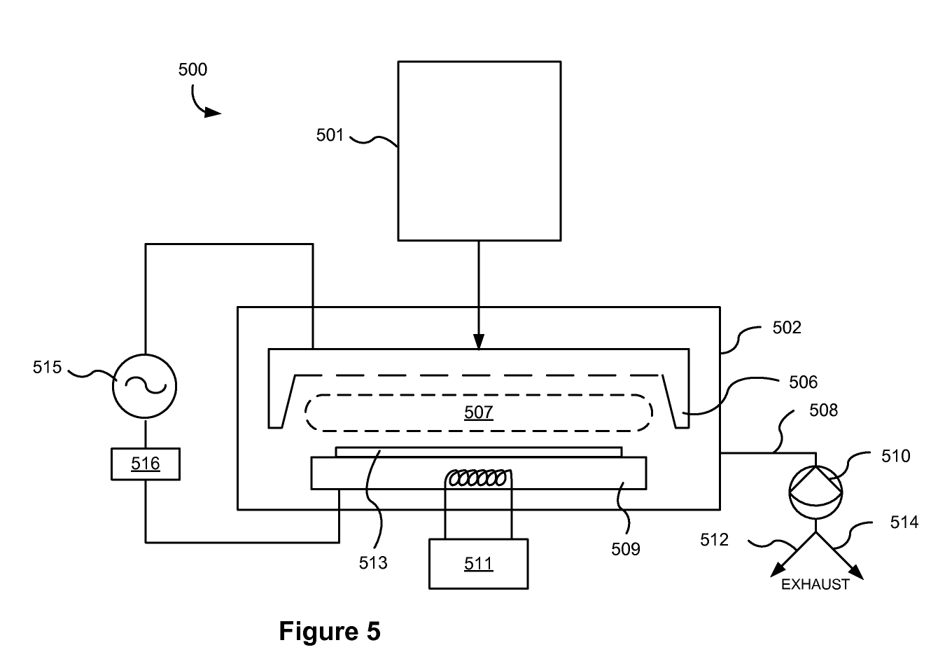

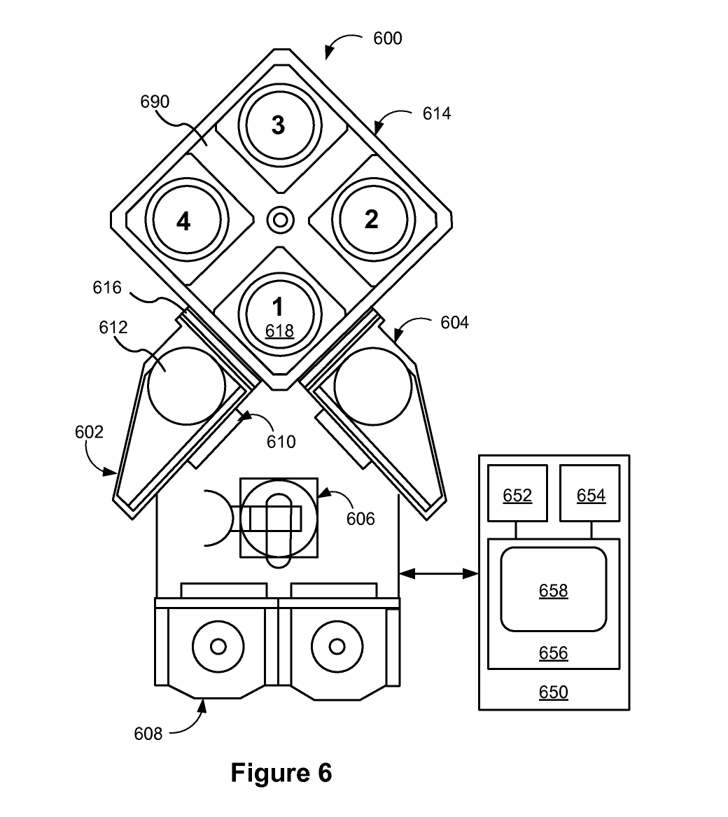

FIG. 5 schematically shows a CFD process station 500 suitable for use with a split-pumping system. For simplicity, CFD process station 500 is depicted as a standalone process station having a process chamber body 502 for maintaining a low-pressure environment. However, it will be appreciated that a plurality of CFD process stations 500 may be included in a common low-pressure process tool environment. While the implementation depicted in FIG. 5 shows one process station, it will be appreciated that, in some implementations, a plurality of process stations may be included in a processing tool. For example, FIG. 6 depicts an implementation of a multi-station processing tool 600. Further, it will be appreciated that, in some implementations, one or more hardware parameters of CFD process station 500, including those discussed in detail below, may be adjusted programmatically by one or more computer controllers.

A CFD process station 500 may fluidly communicate with reactant delivery system 501 for delivering process gases, as well as inert carrier gases, to a distribution showerhead 506. The showerhead 506 may distribute process gases towards substrate 513. In the implementation shown in FIG. 5, the substrate 513 is located beneath showerhead 506, and is shown resting on a pedestal 509. It will be appreciated that the showerhead 506 may have any suitable shape, and may have any suitable number and arrangement of ports for distributing processes gases across the substrate 513.

In some implementations, a microvolume 507 may be located beneath showerhead 506. Performing a CFD process within a microvolume rather than in the entire volume of a process station may reduce reactant exposure and sweep times, may reduce times for altering CFD process conditions (e.g., pressure, temperature, etc.), may limit an exposure of process station robotics to process gases, etc. Example microvolume sizes include, but are not limited to, volumes between 0.1 liter and 2 liters.

In some implementations, pedestal 509 may be raised or lowered to expose substrate 513 to microvolume 507 and/or to vary a volume of microvolume 507. For example, in a substrate transfer phase, pedestal 509 may be lowered to allow substrate 513 to be loaded onto pedestal 509. During a CFD process phase, pedestal 509 may be raised to position substrate 513 within the microvolume 507. In some implementations, the microvolume 507 may completely enclose the substrate 513 as well as a portion of pedestal 509 to create a region of high flow impedance during a CFD process.

Optionally, pedestal 509 may be lowered and/or raised during portions of the CFD process to modulate process pressure, reactant concentration, etc., within the microvolume 507. In one implementation where the process chamber body 502 remains at a base pressure during the CFD process, lowering the pedestal 509 may allow the microvolume 507 to be evacuated. Example ratios of microvolume to process chamber volume include, but are not limited to, volume ratios between 1:500 and 1:10. It will be appreciated that, in some implementations, the pedestal height may be adjusted programmatically by a suitable computer controller.

In some implementations, adjusting the height of the pedestal 509 may allow a plasma density to be varied during plasma activation and/or treatment cycles included in the CFD process. At the conclusion of the CFD process phase, pedestal 509 may be lowered during another substrate transfer phase to allow removal of substrate 513 from pedestal 509.

While the example microvolume variations described herein refer to a height-adjustable pedestal, it will be appreciated that, in some implementations, a position of the showerhead 506 may be adjusted relative to the pedestal 509 to vary the microvolume 507. Further, it will be appreciated that the vertical positions of the pedestal 509 and/or the showerhead 506 may be varied by any suitable mechanism. One of ordinary skill in the art would appreciate that such mechanism may, for example, be provided by hydraulics, pneumatics, spring mechanisms, solenoids and the like. In some implementations, the pedestal 509 may include a rotational mechanism, for example along an axis perpendicular to the surface of the substrate, to provide for rotation of the substrate 513 during processing. It will be appreciated that, in some implementations, one or more of these example adjustments may be performed programmatically by one or more suitable computer controllers.

Returning to the implementation shown in FIG. 5, showerhead 506 and pedestal 509 may electrically communicate with RF power supply 515 and matching network 516 configured for powering a plasma within the microvolume 507. In some implementations, the plasma energy may be controlled by controlling one or more of a process station pressure, a gas concentration, an RF source power, an RF source frequency, and a plasma power pulse timing. For example, the RF power supply 515 and the matching network 516 may be operated at any suitable power level to form a plasma having a desired composition of radical species. Examples of suitable power levels include, but are not limited to, power levels between 100 W and 5000 W. Likewise, the RF power supply 515 may provide RF power of any suitable frequency. In some implementations, the RF power supply 515 may be configured to control high- and low-frequency RF power sources independently of one another. Example low-frequency RF frequencies may include, but are not limited to, frequencies between 50 kHz and 500 kHz. Example high-frequency RF frequencies may include, but are not limited to, frequencies between 1.8 MHz and 2.45 GHz. It will be appreciated that any suitable parameters may be modulated discretely or continuously to provide plasma energy for the surface reactions. In one non-limiting example, the plasma power may be intermittently pulsed to reduce ion bombardment with the substrate surface relative to continuously powered plasmas.

In some implementations, the plasma may be monitored in-situ by one or more plasma monitors. In one implementation, plasma power is monitored by one or more voltage/current sensors (e.g., VI probes). In another implementation, plasma density and/or process gas concentration may be measured by one or more optical emission spectroscopy sensors (OES). In some implementations, one or more plasma parameters are programmatically adjusted based on measurements from such in-situ plasma monitors. For example, an OES sensor may be used in a feedback loop for providing programmatic control of plasma power. It will be appreciated that, in some implementations, other monitors may be used to monitor the plasma and other process characteristics. Such monitors include, but are not limited to, infrared (IR) monitors, acoustic monitors, and pressure transducers.

In some implementations, the plasma is controlled via input/output control (IOC) sequencing instructions. For example, the instructions for setting plasma conditions for a plasma process phase may be included in a corresponding plasma activation recipe phase of a CFD process recipe. In some implementations, process recipe phases may be sequentially arranged, so that all instructions for a CFD process phase are executed concurrently with that process phase. It will be appreciated that some aspects of plasma generation may have well-characterized transient and/or stabilization times that may prolong a plasma process phase. Put another way, such time delays may be predictable. Such time delays may include a time to strike the plasma and a time to stabilize the plasma at the indicted power setting.

In some implementations, pedestal 509 may be temperature-controlled via heater 511 or other suitable equipment. Further, in some implementations, pressure control for CFD process station 500 may be provided by a throttling component of a common foreline valve 510, such as a butterfly valve, located on a common foreline 508. A shut-off component, e.g., a gate valve or other mechanically-sealing valve, may also be provided in the common foreline valve 510. As shown in FIG. 5, the throttling component in the common foreline valve 510 throttles a vacuum provided by downstream vacuum pumps (not shown) separately connected with a first foreline 512 and a second foreline 514 of a split-pumping system similar to that shown in FIG. 1. In some implementations, however, pressure control of process station 500 may also be adjusted by varying an inlet flow rate of one or more gases introduced to CFD process station 500.

With further reference to FIG. 5, in one example of a CFD context for deposition of SiN, a wafer may be exposed to a reactant (precursor) A (e.g., Tertiary Butyl Amine) and the reaction chamber may be purged of reactant A via the first foreline 512. The wafer may then be exposed to reactant (precursor) B (e.g., SiCl2H2) and the reaction chamber may be purged of reactant B via the second foreline 514. Even deposition of 100A of SiN can lead to a substantial buildup of salt in the common foreline due to the mixing of reactants A and B. By providing a plurality (n>1) of vacuum forelines (e.g., the first foreline 512 and the second foreline 514 and associated separate vacuum pumps (not shown, but see the configuration of FIG. 1) the problem of reaction product formation in the exhaust system is substantially reduced or eliminated, and increased costs of operation are thereby avoided. In many preferred implementations, n=2 for two-reactant deposition chemistries.

The present inventors have implemented a prototype split-pumping system on a representative ALD processing tool using high-speed, non-contact throttle valves as the foreline valves. Whereas the representative ALD processing tool required that accumulated reaction products be cleaned out of the exhaust line every few days prior to installation of the split-pumping system, the representative ALD processing tool has run for approximately 9 months without requiring downtime for exhaust line cleaning.

As described above, one or more process stations may be included in a multi-station processing tool. FIG. 6 shows a schematic view of a multi-station processing tool, 600, with an inbound load lock 602 and an outbound load lock 604, either or both of which may comprise a remote plasma source. A robot 606, at atmospheric pressure, is configured to move wafers from a cassette loaded through a pod 608 into inbound load lock 602 via an atmospheric port 610. A wafer is placed by the robot 606 on a pedestal 612 in the inbound load lock 602, the atmospheric port 610 is closed, and the load lock is pumped down. Where the inbound load lock 602 comprises a remote plasma source, the wafer may be exposed to a remote plasma treatment in the load lock prior to being introduced into a processing chamber 614. Further, the wafer also may be heated in the inbound load lock 602 as well, for example, to remove moisture and adsorbed gases. Next, a chamber transport port 616 to processing chamber 614 is opened, and another robot (not shown) places the wafer into the reactor on a pedestal of a first station shown in the reactor for processing. While the implementation depicted in FIG. 6 includes load locks, it will be appreciated that, in some implementations, direct entry of a wafer into a process station may be provided.

The depicted processing chamber 614 comprises four process stations, numbered from 1 to 4 in the implementation shown in FIG. 6. Each station has a heated pedestal (shown at 618 for station 1), and gas line inlets. It will be appreciated that in some implementations, each process station may have different or multiple purposes. For example, in some implementations, a process station may be switchable between a CFD and PECVD process mode. Additionally or alternatively, in some implementations, processing chamber 614 may include one or more matched pairs of CFD and PECVD process stations. While the depicted processing chamber 614 comprises four stations, it will be understood that a processing chamber according to the present disclosure may have any suitable number of stations. For example, in some implementations, a processing chamber may have five or more stations, while in other implementations a processing chamber may have three or fewer stations.

FIG. 6 also depicts a wafer handling system 690 for transferring wafers within processing chamber 614. In some implementations, wafer handling system 690 may transfer wafers between various process stations and/or between a process station and a load lock. It will be appreciated that any suitable wafer handling system may be employed. Non-limiting examples include wafer carousels and wafer handling robots. FIG. 6 also depicts a system controller 650 employed to control process conditions and hardware states of process tool 600. System controller 650 may include one or more memory devices 656, one or more mass storage devices 654, and one or more processors 652. Processor 652 may include a CPU or computer, analog and/or digital input/output connections, stepper motor controller boards, etc.

In some implementations, system controller 650 controls all of the activities of process tool 600. System controller 650 executes system control software 658 stored in mass storage device 654, loaded into memory device 656, and executed on processor 652. System control software 658 may include instructions for controlling the timing, mixture of gases, chamber and/or station pressure, chamber and/or station temperature, wafer temperature, target power levels, RF power levels, substrate pedestal, chuck and/or susceptor position, and other parameters of a particular process performed by process tool 600. System control software 658 may be configured in any suitable way. For example, various process tool component subroutines or control objects may be written to control operation of the process tool components necessary to carry out various process tool processes. System control software 658 may be coded in any suitable computer readable programming language.

In some implementations, system control software 658 may include input/output control (IOC) sequencing instructions for controlling the various parameters described above. For example, each phase of a CFD process may include one or more instructions for execution by system controller 650. The instructions for setting process conditions for a CFD process phase may be included in a corresponding CFD recipe phase. In some implementations, the CFD recipe phases may be sequentially arranged, so that all instructions for a CFD process phase are executed concurrently with that process phase.

Other computer software and/or programs stored on mass storage device 654 and/or memory device 656 associated with system controller 650 may be employed in some implementations. Examples of programs or sections of programs for this purpose include a substrate positioning program, a process gas control program, a pressure control program, a heater control program, and a plasma control program.

A substrate positioning program may include program code for process tool components that are used to load the substrate onto pedestal 618 and to control the spacing between the substrate and other parts of process tool 600.

A process gas control program may include code for controlling gas composition and flow rates and optionally for flowing gas into one or more process stations prior to deposition in order to stabilize the pressure in the process station. A pressure control program may include code for controlling the pressure in the process station by regulating, for example, a throttle valve in the exhaust system of the process station, a gas flow into the process station, and, in particular with regard to the present invention, gas flow out of the process station through separate exhaust lines as described herein, etc.

A heater control program may include code for controlling the current to a heating unit that is used to heat the substrate. Alternatively, the heater control program may control delivery of a heat transfer gas (such as helium) to the substrate.

A plasma control program may include code for setting RF power levels applied to the process electrodes in one or more process stations.

In some implementations, there may be a user interface associated with system controller 650. The user interface may include a display screen, graphical software displays of the apparatus and/or process conditions, and user input devices such as pointing devices, keyboards, touch screens, microphones, etc.

In some implementations, parameters adjusted by system controller 650 may relate to process conditions. Non-limiting examples include process gas composition and flow rates, temperature, pressure, plasma conditions (such as RF bias power levels), pressure, temperature, etc. These parameters may be provided to the user in the form of a recipe, which may be entered utilizing the user interface.

Signals for monitoring the process may be provided by analog and/or digital input connections of system controller 650 from various process tool sensors. The signals for controlling the process may be output on the analog and digital output connections of process tool 600. Non-limiting examples of process tool sensors that may be monitored include mass flow controllers, pressure sensors (such as manometers), thermocouples, etc. Appropriately programmed feedback and control algorithms may be used with data from these sensors to maintain process conditions.

The system controller 650 may provide program instructions for implementing the above-described deposition processes. The program instructions may control a variety of process parameters, such as DC power level, RF bias power level, pressure, temperature, etc. The instructions may control the parameters to operate in-situ deposition of film stacks according to various implementations described herein.

The system controller will typically include one or more memory devices and one or more processors configured to execute the instructions so that the apparatus will perform a method in accordance with the present invention. Machine-readable media containing instructions for controlling process operations in accordance with the present invention may be coupled to the system controller.

The apparatus/process described herein may be used in conjunction with lithographic patterning tools, e.g., steppers, or processes, for example, for the fabrication or manufacture of semiconductor devices, displays, LEDs, photovoltaic panels and the like. Typically, though not necessarily, such tools/processes will be used or conducted together in a common fabrication facility. Lithographic patterning of a film typically comprises some or all of the following steps, each step enabled with a number of possible tools: (1) application of photoresist on a workpiece, i.e., substrate, using a spin-on or spray-on tool; (2) curing of photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferring the resist pattern into an underlying film or workpiece by using a dry or plasma-assisted etching tool; and (6) removing the resist using a tool such as an RF or microwave plasma resist stripper. In one implementation, a SiN film is formed using a method as described herein. The SiN film is used, for example, for one of the purposes described herein. Further, the method may include one or more steps (1)-(6) described above.

While many examples discussed herein include two reactants (A and B), it will be appreciated that any suitable number of reactants may be employed within the scope of the present disclosure. In some implementations, a single reactant and an inert gas used to supply plasma energy for a surface reaction can be used. Alternatively, some implementations may use multiple reactants to deposit a film. For example, in some implementations, a silicon nitride film may be formed by reaction of a silicon-containing reactant and one or more of a nitrogen-containing reactant, or one or more silicon-containing reactants and a single nitrogen-containing reactant, or more than one of both the silicon-containing reactant and the nitrogen-containing reactant.

Although the foregoing invention has been described in some detail for purposes of clarity of understanding, it will be apparent that certain changes and modifications may be practiced within the scope of the invention. It should be noted that there are many alternative ways of implementing the processes, systems and apparatus of the present invention. Accordingly, the present implementations are to be considered as illustrative and not restrictive, and the invention is not to be limited to the details given herein.

What is claimed is:

1. An apparatus for semiconductor processing operations comprising:
a reaction chamber;
a first foreline fluidly connected with the reaction chamber; and
a second foreline fluidly connected with the reaction chamber, wherein the first foreline is configured to evacuate a first process gas from the reaction chamber and the second foreline is configured to evacuate a second process gas from the chamber.

2. The apparatus of claim 1, wherein the first foreline and the second foreline are both fluidly connected with the reaction chamber downstream of any process gas inlet ports into the reaction chamber.

3. The apparatus of claim 1, wherein the first foreline and the second foreline are fluidly connected with the reaction chamber via separate ports.

4. The apparatus of claim 1, further comprising:
a common foreline fluidly connecting the first foreline and the second foreline to the reaction chamber, the common foreline located upstream of the first foreline and the second foreline.

5. The apparatus of claim 4, further comprising:
a common valve configured to regulate fluid flow of the common foreline, the common valve located between the reaction chamber and the first foreline and between the reaction chamber and the second foreline.

6. The apparatus of claim 6, wherein the common valve includes a throttling component and a shut-off component.

7. The apparatus of claim 1, further comprising:
a first valve located on the first foreline and configured to regulate fluid flow through the first foreline; and
a second valve located on the second foreline and configured to regulate fluid flow through the second foreline.

8. The apparatus of claim 7, wherein the first valve and the second valve are both non-sealing, high-speed throttle valves.

9. The apparatus of claim 8, wherein the non-sealing, high-speed throttle valves have actuation speeds of less than 1 second and leak rates of less than 1000 sccm from 1 atmosphere to vacuum.

10. The apparatus of claim 7, wherein the first valve and the second valve are both mechanically-sealing, high-speed valves.

11. The apparatus of claim 7, further comprising:
a first vacuum pump with a first suction inlet fluidly connected with the first foreline; and
a second vacuum pump with a second suction inlet fluidly connected with the second foreline.

12. The apparatus of claim 11, wherein:
the first vacuum pump and the second vacuum pump have substantially similar performance characteristics, and
the first foreline and the second foreline are substantially the same length and diameter.

13. The apparatus of claim 11, further comprising:
a first exhaust line fluidly connected with a first exhaust outlet of the first vacuum pump and with an abatement system, and
a second exhaust line fluidly connected with a second exhaust outlet of the second vacuum pump and with the abatement system.

14. The apparatus of claim 13, further comprising the abatement system.

15. The apparatus of claim 1, further comprising:
a third foreline fluidly connected with the reaction chamber, wherein the third foreline is configured to evacuate a third process gas from the reaction chamber, the third process gas different from the first process gas and the second process gas.

16. The apparatus of claim 15, wherein the third foreline is fluidly connected with the reaction chamber downstream of any process gas inlet ports in the reaction chamber.

17. The apparatus of claim 7, further comprising:
a controller including one or more processors and one or more memories, wherein:
the one or more processors are communicatively connected with the first valve and the second valve, and
the one or more memories store computer-executable instructions for controlling the one or more processors to:
receive first data indicating that the first process gas is being flowed into the reaction chamber;
responsive to receiving the first data, control the first valve to be in an open state and control the second valve to be in a substantially closed state;
receive second data indicating that the second process gas is being flowed into the reaction chamber; and
responsive to receiving the second data, control the second valve to be in an open state and control the first valve to be in a substantially closed state.

18. The apparatus of claim 15, wherein the one or more memories store further computer-executable instructions for further controlling the one or more processors to:
receive third data indicating that purge gas is being flowed into the reaction chamber in association with purging the first process gas from the reaction chamber;
responsive to receiving the third data, control the first valve to be in an open state and control the second valve to be in a substantially closed state;
receive fourth data indicating that purge gas is being flowed into the reaction chamber in association with purging the second process gas from the reaction chamber; and
responsive to receiving the fourth data, control the second valve to be in an open state and control the first valve to be in a substantially closed state.

19. A system comprising the apparatus of claim 1 and a stepper.

20. A method of performing a semiconductor fabrication process, the method comprising:
a) supplying a first process gas to a wafer reaction area in a reaction chamber;
b) purging the wafer reaction area of the first process gas by performing a first purge operation;
c) drawing a vacuum on a first foreline fluidly connected with, and downstream of any process gas inlet ports in, the reaction chamber during (b);
d) supplying a second process gas to the wafer reaction area;
e) purging the wafer reaction area of the second process gas by performing a second purge operation; and
f) drawing a vacuum on a second foreline fluidly connected with, and downstream of any process gas inlet ports in, the reaction chamber during (e), the second foreline separated from the first foreline such that gases in the first foreline do not mix with gases in the second foreline while the gases are in the first foreline and the second foreline.

21. The method of claim 20, further comprising repeating (a) through (f) one or more times.

22. The method of claim 20, further comprising:
g) drawing a vacuum on the first foreline during (a); and
h) drawing a vacuum on the second foreline during (d).

23. The method of claim 22, further comprising repeating (a) through (h) one or more times.
